(19) United States
(12) Patent Application Publication
(10) Pub. No.: US 2012/0193671 A1
(43) Pub. Date: Aug. 2, 2012

(54) LIGHT-EMITTING DIODE DEVICE AND METHOD FOR MANUFACTURING THE SAME

(75) Inventor: Chu-Mo CHIEN, Tainan City (TW)

(73) Assignee: CHI MEI LIGHTING TECHNOLOGY CORP., Tainan City (TW)

(21) Appl. No.: 13/363,387

(22) Filed: Feb. 1, 2012

(30) Foreign Application Priority Data
Feb. 1, 2011 (TW) 100103924
Feb. 17, 2011 (TW) 100105278

(51) Int. Cl. H01L 33/62; H01L 33/52

(52) U.S. Cl. 257/99; 438/26; 257/E33.066; 257/E33.059

(57) ABSTRACT

A light-emitting diode device and a method for manufacturing the same are described. The light-emitting diode device includes a metal heat dissipation bulk, a frame, a light-emitting diode chip and a package encapsulant. The metal heat dissipation bulk includes a curve protrusion ring. The frame is disposed on the metal heat dissipation bulk outside the curve protrusion ring. The frame includes at least two electrode pads respectively disposed at two sides of the curve protrusion ring. The light-emitting diode chip is disposed on the metal heat dissipation bulk in an inner side of the curve protrusion ring. The light-emitting diode chip has a first electrode and a second electrode of different conductivity types, and the first electrode and the second electrode are electrically connected to the electrode pads respectively. The package encapsulant encapsulates the light-emitting diode chip, the curve protrusion ring, and a portion of each electrode pad.

### RELATED APPLICATIONS

This application claims priority to Taiwan Application Serial Number 100105278, filed Feb. 17, 2011 and Taiwan Application Serial Number 100103924, filed Feb. 1, 2011, which are herein incorporated by reference.

### Field of the invention

The present invention relates to a light-emitting device, and more particularly to a light-emitting diode (LED) device and a method for manufacturing the same.

### BACKGROUND OF THE INVENTION

As a light-emitting diode device is applied to a high brightness product, such as an illumination device and a headlight, an operation power of a light-emitting diode chip has to be increased. However, about 80% of the inputting electric power of the light-emitting diode chip is transformed into thermal energy, and only about 20% of the inputting electric power is transformed into light energy. Therefore, as the thermal energy generated by the light-emitting diode chip is increased, a heat dissipation requirement of the light-emitting diode device is increasingly raised.

Currently, heat dissipation technologies for a package procedure of the light-emitting diode chip include the following types. One heat dissipation technology is using silver glue or solder paste to fix the light-emitting diode chip onto a package having a heat dissipation design. An advantage of the technology is that with the package having the heat dissipation design, the heat dissipation efficiency of the light-emitting diode chip is improved. However, a disadvantage of the technology is that the thermal resistance of the silver glue and solder paste used to connect the light-emitting diode chip and the package is very large, so that the heat dissipation efficiency of the package cannot be effectively spread out due to the existence of the silver glue or the solder paste.

Another heat dissipation technology is using an acid and alkali-resistant adhesive tape and a plating technique to directly plate a high heat conductivity metal substrate on a bottom of a light-emitting diode chip as a metal heat dissipation bulk of the light-emitting diode chip. An advantage of the technology is that the light-emitting diode chip and the metal heat dissipation bulk are directly connected with each other without using silver glue or solder paste for bonding, so that the heat dissipation efficiency is much better than that of the aforementioned heat dissipation technology.

However, one disadvantage of the heat dissipation technology is that after the plating of the metal heat dissipation bulk is completed, a large amount of glue residues remain on a front surface of the light-emitting diode chip during the process of removing the adhesive tape. The glue residues cannot be effectively removed, thereby damaging the light-emitting diode chip.

In addition, the adhesive tape is not only used to fix the light-emitting diode chip on a temporary substrate, but also used to protect a light-emitting layer and electrodes of the light-emitting diode chip from damage during the process. However, the experimental results indicate that although the front surface of the light-emitting diode chip is pressed in the adhesive tape, the adhesive tape cannot effectively protect the light-emitting layer and the electrodes of the light-emitting diode chip during the process of forming the metal heat dissipation bulk. As a result, a metal material of the metal heat dissipation bulk is still formed on a side surface and the front surface of the light-emitting diode chip, and the light-emitting diode chip is damaged, so that the yield of the device is worse, thereby decreasing the production efficiency.

Furthermore, in the process, a depth of the light-emitting diode chip embedded in the metal heat dissipation bulk cannot be effectively controlled with the using of the adhesive tape. As a result, lateral light of the light-emitting diode chip may not be successfully extracted from the light-emitting diode device due to the depth of the light-emitting diode chip embedded in the metal heat dissipation bulk is too large.

Moreover, a reflective mirror may be firstly formed on the side surface of the light-emitting diode chip, and then the metal heat dissipation bulk is formed. However, after the lateral light of the light-emitting diode chip is reflected by the reflective mirror and is extracted from the device, the lateral light only can be turned to axial light emitted from a front surface of the light-emitting diode device, so that it cannot fulfill the requirement of the product needing lateral light.

In addition, the price of the acid and alkali-resistant adhesive is much higher than that of a blue tape generally used in a typical light-emitting diode process, and is usually higher than ten times. Therefore, the manufacture cost of the light-emitting diode device is greatly increased with the application of the package heat dissipation technology.

### SUMMARY OF THE INVENTION

Therefore, one aspect of the present invention is to provide a light-emitting diode device and a method for manufacturing the same, in which a light-emitting diode chip and a frame can be simultaneously fixed by a hot melt adhesive, so that the process is simple and is easy to be implemented.

Another aspect of the present invention is to provide a light-emitting diode device and a method for manufacturing the same, in which a hot melt adhesive is formed on a side surface of a light-emitting diode chip, so that it can ensure that the side surface of the light-emitting diode chip is not covered by a metal heat dissipation bulk, thereby effectively preventing lateral light of the light-emitting diode chip from being reflected by the metal heat dissipation bulk covered on the side surface of the light-emitting diode chip. Therefore, the lateral light extraction efficiency of the light-emitting diode device is increased, and the light-emitting efficiency of the light-emitting diode device is enhanced.

Still another aspect of the present invention is to provide a light-emitting diode device and a method for manufacturing the same, in which a hot melt adhesive is formed on a side surface of a frame, so that when a metal heat dissipation bulk is formed subsequently, it can ensure that the side surface of the frame is not covered by the metal heat dissipation bulk. Therefore, it can effectively prevent a short circuit between electrode pads on the frame and the metal heat dissipation bulk from occurring, thereby greatly enhancing the process yield and the product reliability.

Further another aspect of the present invention is to provide a light-emitting diode device and a method for manufacturing the same, in which a bottom of a light-emitting diode chip is directly connected with a metal heat dissipation bulk, so that the light-emitting diode device has superior heat dissipation efficiency.

Yet another aspect of the present invention is to provide a light-emitting diode device and a method for manufacturing the same, in which a cup structure for packaging is unnecessary.

Still further another aspect of the present invention is to provide a light-emitting diode device and a method for manufacturing the same, in which metal can be used to form a body of a frame, so that the light-emitting diode device has better heat dissipation efficiency.

Yet further another aspect of the present invention is to provide a light-emitting diode device and a method for manufacturing the same, in which when a cavity for receiving a light-emitting diode chip is formed in a metal substrate of a frame, conductive leads of the light-emitting diode device can be simultaneously formed in the metal substrate by a simple mechanical processing method. Therefore, the manufacturing of the conductive leads of the light-emitting diode device is easy.

According to the aforementioned aspects, the present invention provides a light-emitting diode device, which includes a metal heat dissipation bulk, a frame, a light-emitting diode chip and a package encapsulant. The metal heat dissipation bulk includes a curve protrusion ring. The frame is disposed on the metal heat dissipation bulk outside the curve protrusion ring. The frame includes at least two electrode pads respectively disposed at two sides of the curve protrusion ring. The light-emitting diode chip is disposed on the metal heat dissipation bulk in an inner side of the curve protrusion ring. The light-emitting diode chip has a first electrode and a second electrode of different conductivity types, and the first electrode and the second electrode are electrically connected to the electrode pads respectively. The package encapsulant encapsulates the light-emitting diode chip, the curve protrusion ring, and a portion of each of the electrode pads.

According to one embodiment of the present invention, the metal heat dissipation bulk includes a metal heat dissipation layer and a metal layer covering the metal heat dissipation layer.

According to another embodiment of the present invention, the metal heat dissipation bulk is further set with a first trench passing through the metal heat dissipation bulk to electrically separate the electrode pads at two sides of the first trench. In addition, the frame is further set with two through holes passing through the frame, and the frame includes two conductive leads respectively disposed in the through holes to electrically connect the electrode pads to the metal heat dissipation bulk at the sides of the first trench respectively.

According to still another embodiment of the present invention, the metal heat dissipation bulk is further set with a second trench, and the first trench and the second trench are located at two sides of the light-emitting diode chip.

According to the aforementioned aspects, the present invention further provides a method for manufacturing a light-emitting diode device, which includes the following steps. A temporary substrate is provided. A hot melt adhesive layer is formed on the temporary substrate. A frame is embedded in the hot melt adhesive layer. The frame includes at least two portions, and each portion is set with an electrode pad. A light-emitting diode chip is embedded in the hot melt adhesive layer between the portions. The light-emitting diode chip includes a first electrode and a second electrode of different conductivity types, and the hot melt adhesive layer has a curve cavity ring between the light-emitting diode chip and the frame. A metal heat dissipation bulk is formed to cover the frame, the light-emitting diode chip and the hot melt adhesive layer, and to fill up the curve cavity ring so as to make the metal heat dissipation bulk include a curve protrusion ring. The temporary substrate and the hot melt adhesive layer are removed to expose the light-emitting diode chip, the first electrode, the second electrode, the frame, the electrode pads and the curve protrusion ring. The first electrode and the second electrode are electrically connected to the electrode pads respectively. A package encapsulant is formed to encapsulate the light-emitting diode chip, the curve protrusion ring and a portion of each electrode pad.

According to one embodiment of the present invention, a material of the hot melt adhesive layer may include ethylene-vinyl acetate (EVA), polyolefin polymer, polyamide resin or wax.

According to another embodiment of the present invention, the step of forming the metal heat dissipation bulk may include: forming a metal layer to cover the frame, the light-emitting diode chip and the hot melt adhesive layer; and forming a metal heat dissipation layer to cover the metal layer and to fill up the curve cavity ring.

According to still another embodiment of the present invention, before the step of embedding the frame, the method for manufacturing the light-emitting diode device further includes forming the frame. The step of forming the frame includes: forming two through holes to respectively pass through the portions of the frame, in which the through holes respectively expose portions of the electrode pads; and forming two conductive leads to respectively fill the through holes. In addition, the step of forming the metal heat dissipation bulk may further include: forming a first trench to pass through the metal heat dissipation bulk to electrically separate the electrode pads at two sides of the first trench. The conductive leads electrically connect the electrode pads to the metal heat dissipation bulk at the sides of the first trench respectively.

According to further another embodiment of the present invention, the step of forming the metal heat dissipation bulk may further include forming a second trench to pass through the metal heat dissipation bulk, and the first trench and the second trench are located at two sides of the light-emitting diode chip.

According to yet another embodiment of the present invention, the step of forming the metal heat dissipation bulk further includes forming two insulation layers to respectively fill the first trench and the second trench.

According to still further another embodiment of the present invention, the step of removing the temporary substrate and the hot melt adhesive layer may include: performing a heating and melting treatment on the hot melt adhesive layer; separating the temporary substrate and the hot melt adhesive layer; and using an organic dissolvent to remove the hot melt adhesive layer.

The embodiments of the present invention have advantages including that the process is simple, the light-emitting efficiency is enhanced, the lateral light extraction efficiency is increased, the heat dissipation efficiency is increased, and the reliability and the yield are enhanced.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1A through FIG. 1J are schematic flow diagrams showing a method for manufacturing a light-emitting diode device in accordance with an embodiment of the present invention;

FIG. 2A through FIG. 2C are schematic flow diagrams showing a method for manufacturing a frame of a light-emitting diode device in accordance with another embodiment of the present invention;

FIG. 2D illustrates a cross-sectional view of a light-emitting diode device in accordance with still another embodiment of the present invention;

FIG. 3A illustrates a cross-sectional view of a light-emitting diode device in accordance with further another embodiment of the present invention;

FIG. 3B illustrates a back view of the light-emitting diode device of FIG. 3A;

FIG. 4 illustrates a cross-sectional view of a frame of a light-emitting diode device in accordance with still another embodiment of the present invention;

FIG. 5A illustrates a cross-sectional view of a light-emitting diode device in accordance with further another embodiment of the present invention; and

FIG. 5B illustrates a back view of the light-emitting diode device of FIG. 5A.

### DETAILED DESCRIPTION OF THE PREFERRED EMBODIMENT

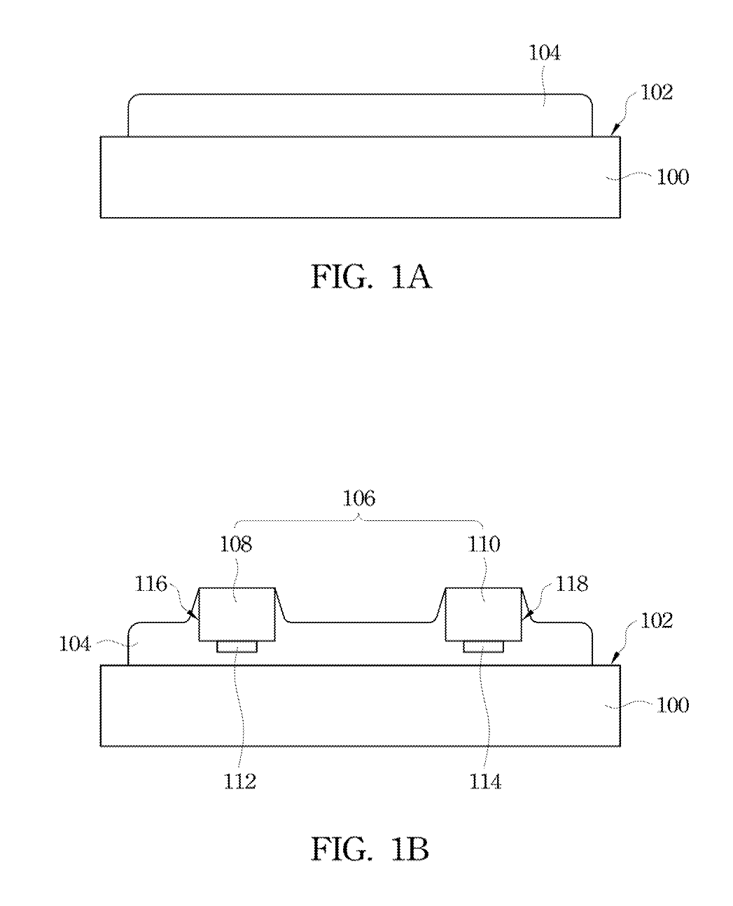

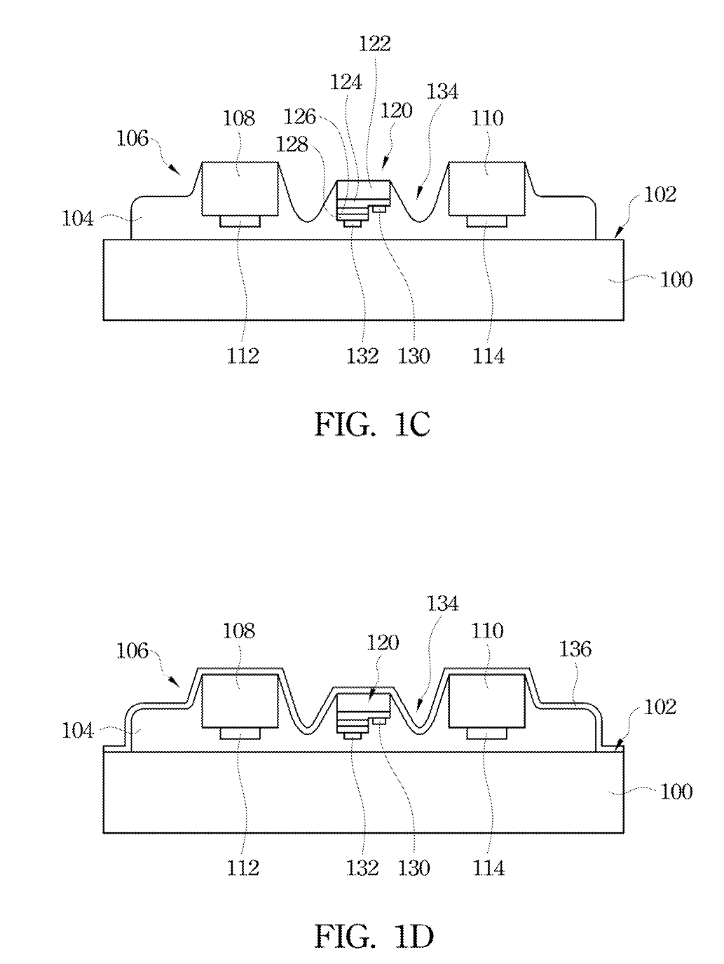

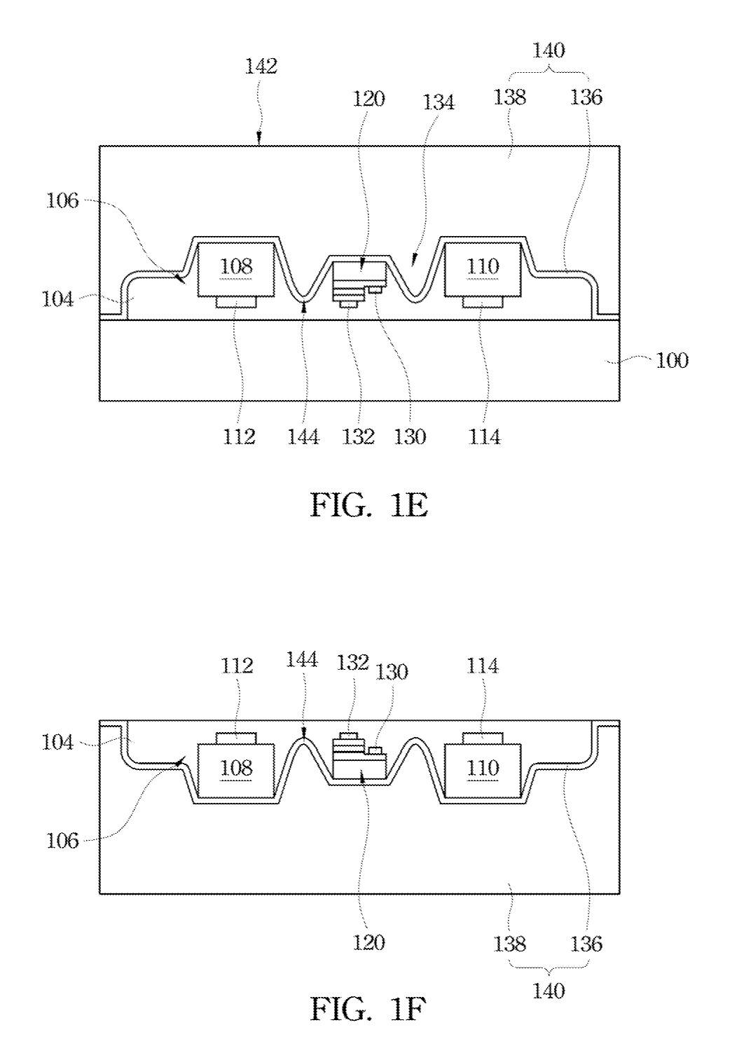

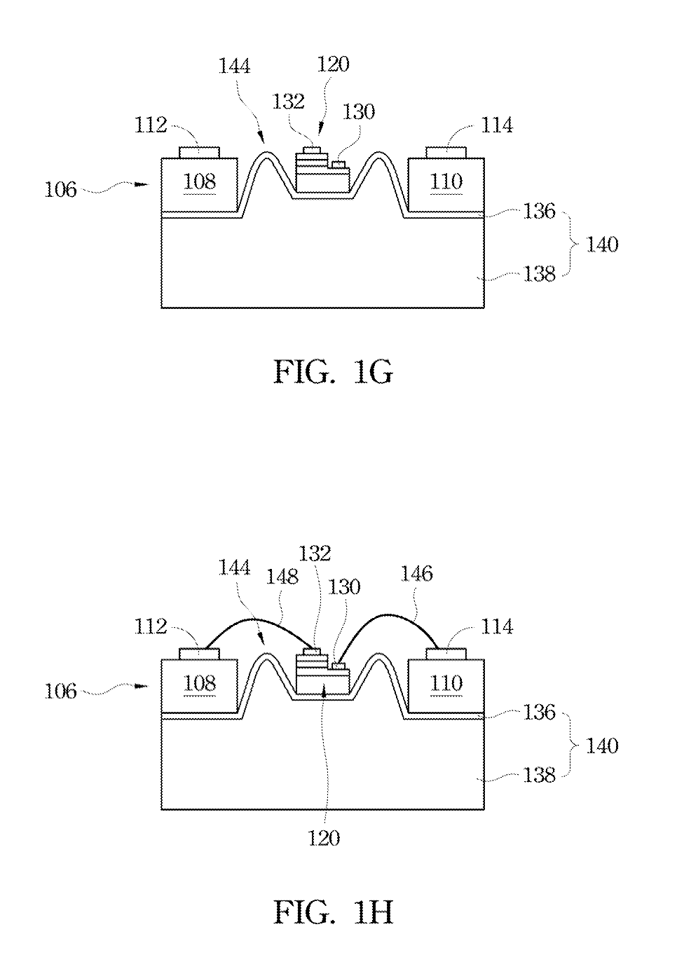

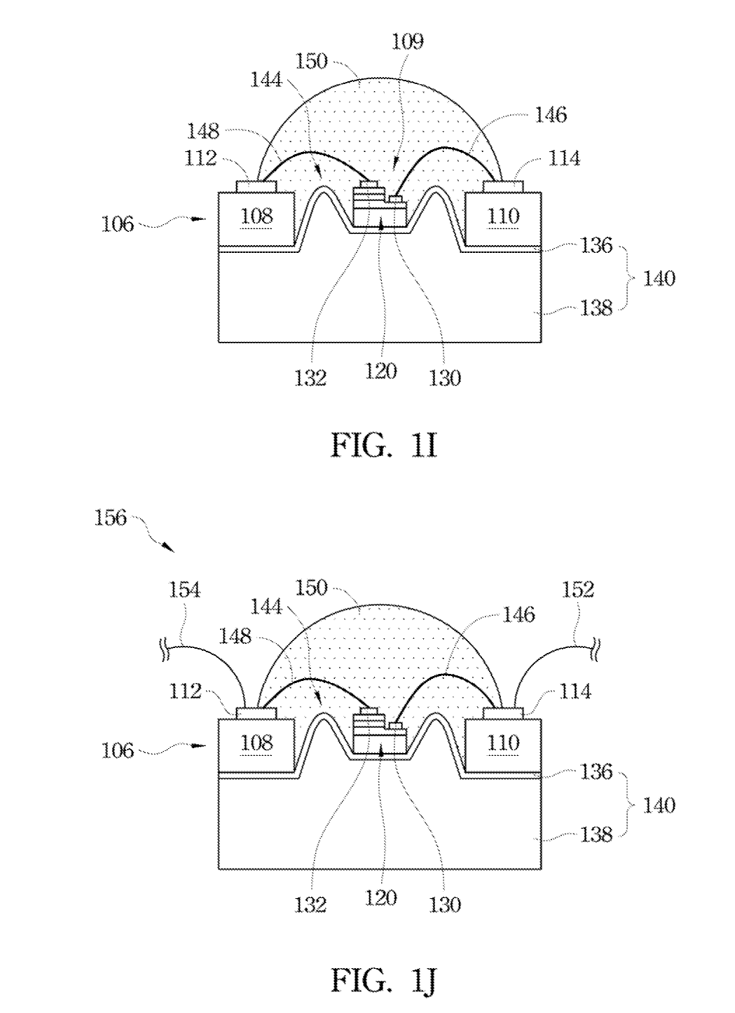

Refer to FIG. 1A through FIG. 1J. FIG. 1A through FIG. 1J are schematic flow diagrams showing a method for manufacturing a light-emitting diode device in accordance with an embodiment of the present invention. In the present embodiment, in the manufacturing of a light-emitting diode device, a temporary substrate 100 is firstly provided. The temporary substrate 100 may be a flat plate, for example. In addition, a material of the temporary substrate 100 preferably adopts a hard, and acid and alkali-resistant material. Then, as shown in FIG. 1A, a hot melt adhesive layer 104 is uniformly formed on a surface 102 of the temporary substrate 100 by a coating method, for example. The hot melt adhesive layer 104 may include ethylene-vinyl acetate (EVA), polyolefin, polyamide resin or wax. A thickness of the hot melt adhesive layer 104 is preferably larger than 10 μm.

Next, as shown in FIG. 1B, a frame 106 is provided and pressed into the hot melt adhesive layer 104 so as to embed the frame 106 into the hot melt adhesive layer 104. The frame 106 includes at least two portions 108 and 110. The two portions 108 and 110 are respectively set with electrode pads 112 and 114. Materials of the portions 108 and 110 preferably adopt insulation materials. In one exemplary embodiment, the materials of the portions 108 and 110 may be sapphire or polyphthalamide (PPA). In addition, the electrode pads 112 and 114 may be respectively formed on the portions 108 and 110 by, for example, a deposition method.

In the present embodiment, when pressing the frame 106 into the hot melt adhesive layer 104, the frame 106 is pressed into the hot melt adhesive layer 104 by facing a side of the frame 106 set with the electrode pads 112 and 114 toward the hot melt adhesive layer 104. Therefore, as shown in FIG. 1B, the hot melt adhesive layer 104 can entirely encapsulate the electrode pads 112 and 114 of the frame 106 to prevent the electrode pads 112 and 114 of the frame 106 from being connected with a metal heat dissipation material formed subsequently to form a short circuit. In addition, after the frame 106 is pressed into the hot melt adhesive layer 104, due to the material property of the hot melt adhesive, the hot melt adhesive layer 104 adheres to a side surface 116 of the portion 108 and a side surface 118 of the portion 110 of the frame 106, and the hot melt adhesive layer 104 forms a curve structure around the side surface 116 of the portion 108 and the side surface 118 of the portion 110 of the hot melt adhesive layer 104.

Next, a light-emitting diode chip, such as a horizontal type light-emitting diode chip 120 shown in FIG. 1C or a common vertical type light-emitting diode chip, is provided. In the present embodiment, the horizontal type light-emitting diode chip 120 is taken as an example for illustration. The light-emitting diode chip 120 mainly includes a substrate 122, a first conductivity type semiconductor layer 124, a light-emitting layer 126, a second conductivity type semiconductor layer 128, and electrodes 130 and 132. The first conductivity type semiconductor layer 124 is disposed on the substrate 122, the light-emitting layer 126 is disposed on a portion of the first conductivity type semiconductor layer 124, the second conductivity type semiconductor layer 128 is disposed on the light-emitting layer 126, the electrode 130 is disposed on an exposed portion of the first conductivity type semiconductor layer 124, and the electrode 132 is disposed on a portion of the second conductivity type semiconductor layer 128, as shown in FIG. 1C. In the present invention, the first conductivity type and the second conductivity type are different conductivity types. For example, one of the first conductivity type and the second conductivity type is n type, and the other one is p type.

Subsequently, the light-emitting diode chip 120 is pressed into the hot melt adhesive layer 104, and the light-emitting diode chip 120 is disposed between the portions 108 and 110 of the frame 106. In the present embodiment, when pressing the light-emitting diode chip 120 into the hot melt adhesive layer 104, the light-emitting diode chip 120 is pressed into the hot melt adhesive layer 104 by making a side of the light-emitting diode chip 120, where the electrodes 130 and 132 are disposed, face the hot melt adhesive layer 104. In addition, after the light-emitting diode chip 120 is pressed into the hot melt adhesive 104, the hot melt adhesive layer 104 adheres to a side surface of the light-emitting diode chip 120 due to the material property of the hot melt adhesive layer 104. Therefore, as shown in FIG. 1C, the hot melt adhesive layer 104 can cover the entire electrodes 130 and 132 of the light-emitting diode chip 120, a side surface of an epitaxial structure composed of the first conductivity type semiconductor layer 124, the light-emitting layer 126 and the second conductivity type semiconductor layer 128. Therefore, with the protection of the hot melt adhesive layer 104, it can effectively prevent the light-emitting diode chip 120 from being damaged in the subsequent deposition process of a metal heat dissipation material.

Furthermore, the hot melt adhesive layer 104 forms a curve structure around the side surface of the light-emitting diode chip 120 similarly. Therefore, as shown in FIG. 1C, after the frame 106 and the light-emitting diode chip 120 are both embedded in the hot melt adhesive layer 104, the hot melt adhesive layer 104 has a curve cavity ring 134 between the light-emitting diode chip 120 and the frame 106.

In the present invention, a frame may include more than two portions, and a plurality of light-emitting diode chips may be provided and respectively disposed between the adjacent two portions. Therefore, a plurality of light-emitting diode devices can be simultaneously fabricated by applying the method of the present invention.

Then, as shown in FIG. 1D, a metal layer 136 is formed to cover the hot melt adhesive layer 104, the frame 106 and the light-emitting diode chip 120 by, for example, a deposition method. The deposition method may be an evaporation method, a sputtering method, an electroless plating method or an electron beam evaporation method. In one exemplary embodiment, the metal layer 136 may be a single-layered structure. In another exemplary embodiment, the metal layer 136 may be a multi-layered compound material structure. A thickness of the metal layer 136 is preferably less than 3 μm.

In one exemplary embodiment, a material of the metal layer 136 may be ITO, Au, Ag, Pt, Pd, Ni, Cr, Ti, Ta, Al, In, W, Cu, or an alloy composed of Ni, Cr, Ti, Ta, Al, In, W or Cu, for example. In a preferred embodiment, the material of the metal layer 136 may be a metal material of high reflectivity, such as Ag, Pt, Al, Au, Ni or Ti. The metal layer 136 also covers the curve cavity ring 134 of the hot melt adhesive layer 104, so that the metal layer 136 is formed with a curve protrusion structure corresponding to the curve cavity ring 134. Therefore, the metal layer 136 can reflect lateral light of the light-emitting diode chip 120, thereby facilitating the extracting of the lateral light of the light-emitting diode chip 120.

Next, as shown in FIG. 1E, a metal heat dissipation layer 138 is formed to cover the metal layer 136 and to fill up the curve cavity ring 134 of the hot melt adhesive layer 104 by, for example, a deposition method. Therefore, the fabrication of a metal heat dissipation bulk 140 composed of the metal layer 136 and the metal heat dissipation layer 138 is completed. In a preferred embodiment, a plating method may be used to deposit the metal heat dissipation layer 138. The metal heat dissipation layer 138 may be thicker to provide the light-emitting diode chip 120 with larger heat dissipation efficiency. In one exemplary embodiment, a thickness of the metal heat dissipation layer 138 may be from 50 μm to 500 μm, for example. A material of the metal heat dissipation layer 138 may be Cu, for example.

In one example, after the deposition of the metal heat dissipation layer 138, a surface 142 of the metal heat dissipation layer 138 may be selectively polished. After polishing, the roughness of the surface 142 of the metal heat dissipation layer 138 (from the uppermost point to the lowest point of the surface 142) is from 80 Å to 10 μm.

The metal heat dissipation bulk 140 covers the hot melt adhesive layer 104 and fills up the curve cavity ring 134 of the hot melt adhesive layer 104, so that the metal heat dissipation bulk 140 has a curve protrusion ring 144 corresponding to the curve cavity ring 134 of the hot melt adhesive layer 104, as shown in FIG. 1E. In addition, the curve cavity ring 134 of the hot melt adhesive layer 104 is located between the light-emitting diode chip 120 and the frame 106, and the light-emitting diode chip 120 is located between the portions 108 and 110 of the frame 106, so that the frame 106 and the light-emitting diode chip 120 are both located on the metal heat dissipation bulk 140, the portions 108 and 110 of the frame 106 are located outside the curve protrusion ring 144, and the light-emitting diode chip 120 is located in an inner side of the curve protrusion ring 144. Furthermore, the electrode pads respectively disposed on the portions 108 and 110 of the frame 106 are respectively disposed at two sides of the curve protrusion ring 144.

Then, the temporary substrate 100 and the hot melt adhesive layer 104 may be removed to expose the light-emitting diode chip 120 and its electrodes 130 and 132, the frame 106 and the electrode pads 112 and 114 thereon, and the curve protrusion ring 144 of the metal heat dissipation bulk 140 covered by the hot melt adhesive layer 104. In one example, the temporary substrate 100 and the hot melt adhesive layer 104 may be removed simultaneously. For example, the temporary substrate 100 is lifted off simultaneously by removing the hot melt adhesive layer 104.

In another exemplary embodiment, as shown in FIG. 1F, a heating plate is used to heat the structure shown in FIG. 1E to perform a heating and melting treatment on the hot melt adhesive layer 104, for example. After the hot melt adhesive layer 104 is heated and melted, the temporary substrate 100 can be separated from the hot melt adhesive layer 104. Next, the structure shown in FIG. 1F may be dipped in an organic dissolvent, such as acetone, isopropyl alcohol or ethyl acetate, so as to remove the hot melt adhesive layer 104 by using the organic dissolvent. As a result, the light-emitting diode chip 120 and its electrodes 130 and 132, the frame 106 and the electrode pads 112 and 114 thereon, and the curve protrusion ring 144 of the metal heat dissipation bulk 140 are exposed, as shown in FIG. 1G.

In some exemplary embodiments, a redundant portion of the metal heat dissipation bulk 140 may be cut to form a structure shown in FIG. 1G by a grinding wheel or a laser, such as a wet laser or a dry laser.

Then, as shown in FIG. 1H, wires 146 and 148 are respectively used to connect the electrode 130 of the light-emitting diode chip 120 to the electrode pad 114, and the electrode 132 to the electrode pad 112 by, for example, a wire-bonding method, so as to electrically connect the electrodes 130 and 132 to the electrode pads 114 and 112 respectively. For example, the wires 146 and 148 may be Au wires.

Next, as shown in FIG. 1I, an encapsulating procedure is performed by, for example, a dispenser, so as to fill a package encapsulant 150, such as silicone or epoxy, between the portions 108 and 110 of the frame 106. As shown in FIG. 1I, the package encapsulant 150 completely encapsulates the light-emitting diode chip 120, the curve protrusion ring 144 and the wires 146 and 148, and covers a portion of each of the electrode pads 114 and 112. In one exemplary embodiment, the package encapsulant 150 preferably covers a connection of the electrode pad 114 and the wire 146, and a connection of the electrode pad 112 and the wire 148 to ensure the connection reliability between the electrode pad 114 and the wire 146, and between the electrode pad 112 and the wire 148.

The metal heat dissipation bulk 140 and the frame 106 can provide the light-emitting diode chip 120 with strong rigidity support, and the curve protrusion ring 144 of good reflectivity can be formed between the light-emitting diode chip 120 and the frame 106 with the using of the reflective material. Therefore, a subsequent package procedure can be directly performed on a structure shown in FIG. 1I without using a conventional package cup additionally. As shown in FIG. 1J, wires 152 and 154 are respectively used to connect the electrode pads 114 and 112 to an outer power supply (not shown) similarly by, for example, a wire-bonding method, so that the outer power supply can be used to provide the light-emitting diode chip 120 with power. Up to present, the manufacturing of a light-emitting diode device 156 is substantially finished. Similarly, the wires 152 and 154 may be Au wires. In other embodiments, the package encapsulant 150 may be formed after respectively using the wires 152 and 154 to connect the electrode pads 114 and 112 to the outer power supply.

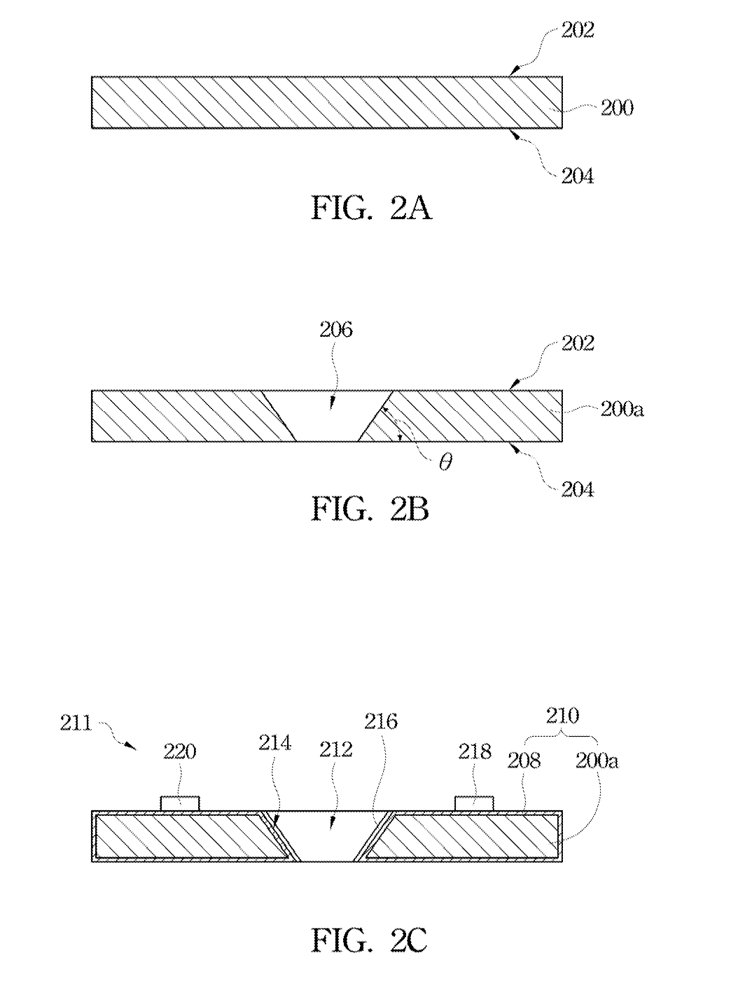

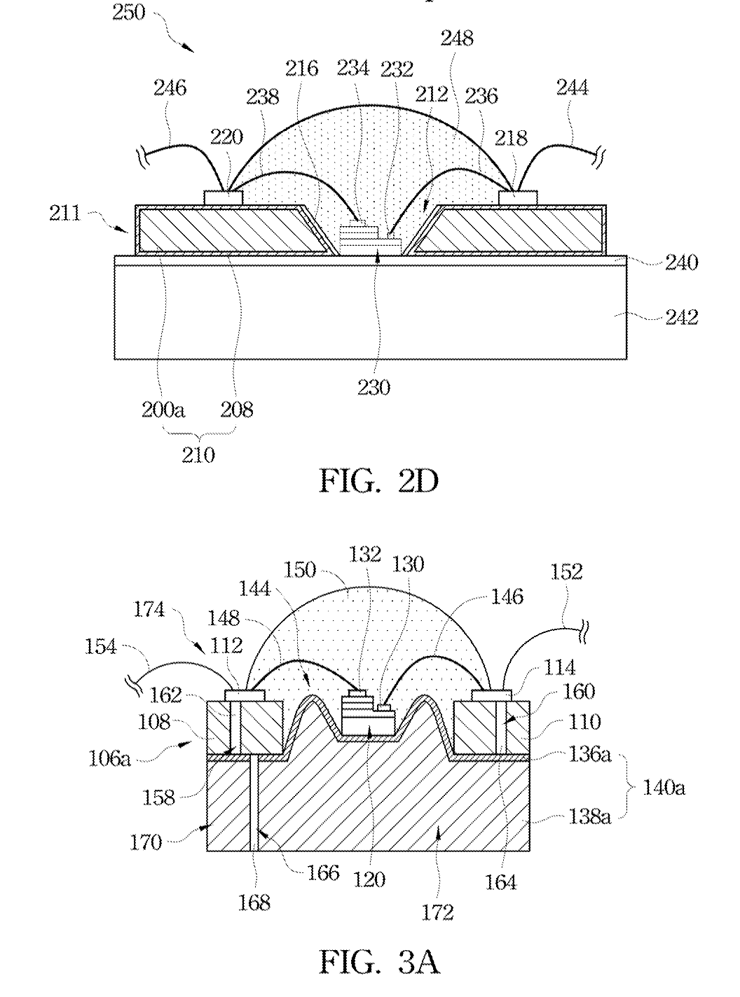

In another exemplary embodiment, a frame of the present invention may be fabricated by using a flat metal plate. Refer to FIG. 2A through FIG. 2C. FIG. 2A through FIG. 2C are schematic flow diagrams showing a method for manufacturing a frame of a light-emitting diode device in accordance with another embodiment of the present invention. In the present embodiment, when a frame 211 shown in FIG. 2C is manufactured, a flat metal plate 200 may be firstly provided. Preferably, a thickness of the flat metal plate 200 is about equal to a depth of a package cavity or a package cup. The flat metal plate 200 has two opposite surfaces 202 and 204. A material of the flat metal plate 200 may use an easily processed metal. In one exemplary embodiment, the material of the flat metal plate 200 may be Al, for example. In another exemplary embodiment, the material of the flat metal plate 200 may be Cu, for example.

Then, as shown in FIG. 2B, a through cavity 206 is formed on a predetermined location of the flat metal plate 200 to form a metal substrate 200a by, for example, a mechanical processing method. The through cavity 206 passes through the surfaces 202 and 204 of the flat metal plate 200. The through cavity 206 may be in the form of a cup. In one exemplary embodiment, an included angle θ between a side surface of the through cavity 206 and the bottom surface 204 of the flat metal plate may be greater than 0 degree and smaller than 90 degrees. In one preferred embodiment, the included angle θ may range from 30 degrees to 60 degrees.

Next, an insulation layer 208 is formed to wrap the metal substrate 200a, so as to form a metal base 210. The insulation layer 208 covers the all surfaces of the metal substrate 200a. In addition, the metal substrate 200a has the through cavity 206, so that the metal base 210 composed the metal substrate 200a and the insulation layer 208 has a cavity 212 passing through the metal base 210.

In one exemplary embodiment, the material of the flat metal plate 200 may include Al, so that an aluminum oxide layer may be formed on the all surfaces of the metal substrate 200a as the insulation layer 208 by, for example, an anodic treatment method. If the aluminum oxide layer is too thick, the heat dissipation and reflection efficiency of the metal base 210 may be decreased. Therefore, the thickness of the aluminum oxide layer is controlled to lower the influence of the aluminum oxide layer on the heat dissipation and reflection efficiency of the metal base 210. In one example, the thickness of the aluminum oxide layer may be from 5 μm to 45 μm. In addition, an appearance color of the aluminum oxide layer is easily partial to dark and has a light-absorbing effect. Therefore, in some another exemplary embodiments, a reflective layer 216 may be selectively formed to cover a side surface 214 of the cavity 212 to increase the light reflectivity of the side surface 214 of the cavity 212 by, for example, a sputtering method or an evaporation method. In one example, a material of the reflective layer 216 may be TiO₂ or Ag, for example.

In another exemplary embodiment, the material of the flat metal plate 200 may include Cu, so that a silicon nitride layer or a silicon dioxide layer may be formed as the insulation layer 208 by, for example a deposition method. In one example, the deposition method may be an electron beam evaporation method or a sputtering method.

Then, as shown in FIG. 2C, electrode pads 218 and 220 are formed on the metal base 210 to complete the manufacturing of the frame 211 by, for example, a deposition, photolithograph and etching process; a deposition and lift-off process; or a screen printing process. The electrode pads 218 and 220 are adjacent to the cavity 212 and at two opposite sides of the cavity 212.

Refer to FIG. 2D. FIG. 2D illustrates a cross-sectional view of a light-emitting diode device in accordance with still another embodiment of the present invention. The present embodiment applies the frame 211 in FIG. 2C to a light-emitting diode device 250. The light-emitting diode device 250 mainly includes a metal heat dissipation bulk, the frame 211, a light-emitting diode chip 230 and a package encapsulant 248.

In one exemplary embodiment, the metal heat dissipation bulk mainly includes a metal heat dissipation layer 242 and a metal layer 240. The metal layer 240 is stacked on the metal heat dissipation layer 242. A structure of the metal heat dissipation bulk of the present embodiment is the same as that of the metal heat dissipation bulk 140 of the aforementioned embodiment. The frame 211 is disposed on the metal layer 240 of the metal heat dissipation bulk. The cavity 212 of the frame 211 exposes a portion of a surface of the metal layer 240. The light-emitting diode chip 230 is disposed in the cavity 212 and on the surface of the metal layer 240 exposed by the cavity 212. A structure of the light-emitting diode chip 230 may be similar to that of the aforementioned light-emitting diode chip 120. The light-emitting diode chip 230 includes electrodes 232 and 234 respectively located on semiconductor layers of different conductivity types of the light-emitting diode chip 230.

Wires 236 and 238 are respectively used to connect the electrode 232 of the light-emitting diode chip 230 to the electrode pad 218, and the electrode 234 to the electrode pad 220, so as to electrically connect the electrodes 232 and 234 to the electrode pads 218 and 220 respectively. For example, the wires 236 and 238 may be Au wires. The package encapsulant 248 fills up the cavity 212 of the frame 211, and encapsulates the cavity 212 and the light-emitting diode chip 230. Similarly, the package encapsulant 248 preferably covers a connection of the electrode pad 218 and the wire 236, and a connection of the electrode pad 220 and the wire 238 to ensure the connection reliability between the electrode pad 218 and the wire 236, and between the electrode pad 220 and the wire 238.

Furthermore, in the present embodiment, wires 244 and 246 are respectively used to connect the electrode pads 218 and 220 of the frame 211 to an outer power supply (not shown) similarly by, for example, a wire-bonding method, so that the outer power supply can be used to provide the light-emitting diode chip 230 with power. Similarly, the wires 244 and 246 may be Au wires.

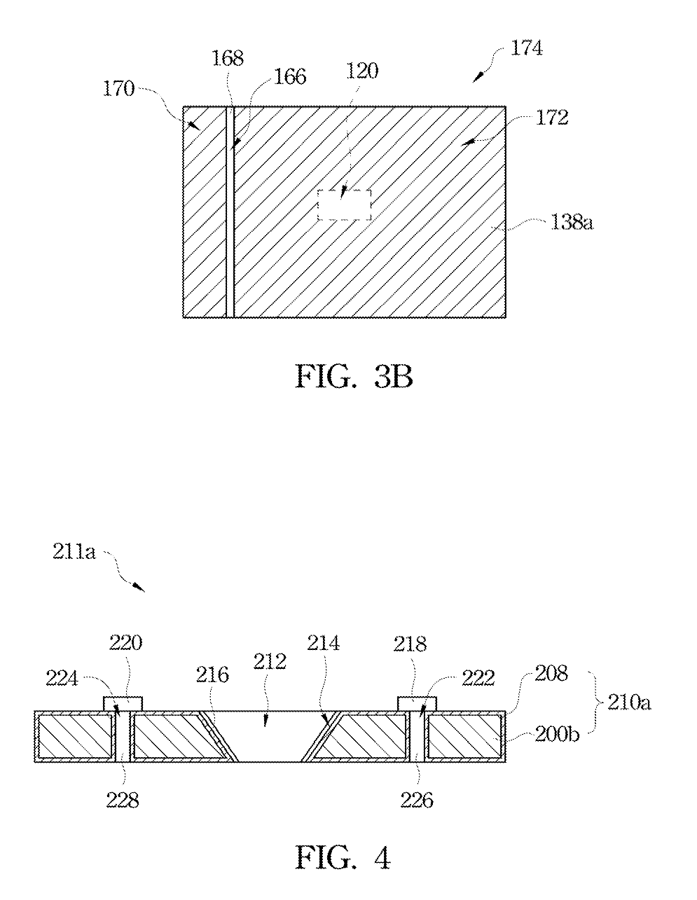

A light-emitting diode device of the present invention may be connected to an outer power supply by other methods without wires. Refer to FIG. 3A and FIG. 3B. FIG. 3A and FIG. 3B respectively illustrate a cross-sectional view and a back view of a light-emitting diode device in accordance with further another embodiment of the present invention. In the present embodiment, a structure of a light-emitting diode device 174 is substantially the same as that of the light-emitting diode device 156 of the aforementioned embodiment. As shown in FIG. 3A, main differences between the light-emitting diode devices 156 and 174 are that: compared with the frame 106, a frame 106a has through holes 158 and 160, and the through holes 158 and 160 are respectively filled with conductive leads 162 and 164; and compared with the metal heat dissipation bulk 140 composed of the metal layer 136 and the metal heat dissipation layer 138, a heat dissipation bulk 140a composed of the metal layer 136a and the metal heat dissipation layer 138a has a trench 166 and an insulation layer 168, which may be selectively filled in the trench 166.

In the manufacturing of the frame 106a, the through holes 158 and 160 are formed on a predetermined location of each of the portions 108 and 110 of the frame 106a by, for example, a mechanical processing method, a water jet laser cutting method or a photolithograph and etching method. The through holes 158 and 160 respectively pass through the portions 108 and 110, and are respectively located at two sides of the light-emitting diode chip 120. The scopes of the electrode pads 112 and 114 cover the predetermined locations of the portions 108 and 110, so that the through holes 158 and 160 respectively expose portions of the electrode pads 112 and 114. After the through holes 158 and 160 are formed, a conductive metal is filled into the through holes 158 and 160 by, for example, an electroless plating method. Therefore, the conductive leads 162 and 164 are respectively formed in the through holes 158 and 160.

As shown in FIG. 3A, the electrode pads 112 and 114 are respectively on an opening at one end of the through hole 158 and an opening at one end of the through hole 160, and respectively cover the openings of the through holes 158 and 160 completely. Therefore, the conductive leads 162 and 164 respectively formed in the through holes 158 and 160 can respectively contact with the electrode pads 112 and 114 to form electrical connections.

Refer to FIG. 2B and FIG. 4 simultaneously. In another embodiment, when the flat metal plate is used to form the frame, two through holes 222 and 224 may be simultaneously formed in predetermined locations of the flat metal plate 200 while the through cavity 206 is formed in the flat metal plate 200 by, for example, a mechanical processing method. The through holes 222 and 224 pass through the flat metal plate 200, and are respectively located at two sides of the through cavity 206. After the through holes 222 and 224 are formed, the insulation layer 208 is formed to cover all surfaces of a metal substrate 200b, including inner side surfaces of the through holes 222 and 224, to form a metal base 210a.

Next, a conductive metal is formed to fill the through holes 222 and 224 by, for example, an electroless plating method. Therefore, conductive leads 226 and 228 are respectively formed in the through holes 222 and 224. Then, the electrode pads 218 and 220 are respectively formed on and covering the through holes 222 and 224, so as to form a frame 211a shown in FIG. 4. In the frame 211a, the conductive leads 226 and 228 respectively formed in the through holes 222 and 224 can respectively contact with the electrode pads 218 and 220 to form electrical connections.

Refer to FIG. 3A again. After the conductive leads 162 and 164 are formed, a metal layer 136a and a metal heat dissipation layer 138a are formed in sequence to cover the light-emitting diode chip 120, the frame 106a and the conductive leads 162 and 164. The metal layer 136a covers and contacts with the conductive leads 162 and 164, so that the conductive leads 162 and 164 can electrically connect the electrode pads 112 and 114 to the metal layer 136a respectively.

In one exemplary embodiment, in the manufacturing of the metal heat dissipation bulk 140a, a continuous metal layer is firstly formed, and then a continuous metal heat dissipation layer is formed to cover the continuous metal layer. Then, the trench 166 is formed in a predetermined location of a stacked structure composed of the continuous metal layer and the metal heat dissipation layer to form the metal heat dissipation bulk 140a by, for example, a mechanical Processing method, a water jet laser cutting method or a photolithograph and etching method.

In one example, when the trench 166 is formed, the frame 106a needs to provide supports to two sides of the whole structure to ensure that the whole structure can be supported well, so that the location of the trench 166 is preferably located within the scope of the frame 106a. As shown in FIG. 3A, one opening at one end of the trench 166 exposes a partial surface of the portion 108 of the frame 106a.

In another exemplary embodiment, in the manufacturing the metal heat dissipation bulk 140a, it can design to make the metal layer 136a is formed to include two separate portions. Then, the metal heat dissipation layer 138a is grown based on the metal layer 136a including two separate portions by, for example, an electroless plating method. Therefore, the metal heat dissipation layer 138a can be formed to include two separate portions while the metal heat dissipation layer 138a is grown by an electroless plating method. Accordingly, as the growing of the metal layer 136a and the metal heat dissipation layer 138a, the trench 166 can be simultaneously formed in the metal heat dissipation bulk 140a composed of the metal layer 136a and the metal heat dissipation layer 138a.

Simultaneously refer to FIG. 3A and FIG. 3B. The trench 166 is formed at one side of the light-emitting diode chip 120 and passes through the metal heat dissipation bulk 140a to divide the metal heat dissipation bulk 140a into two portions 170 and 172. In addition, the conductive leads 162 and 164 of the frame 106a are respectively at two sides of the trench 166, so that with the installation of the trench 166, the electrode pads 112 and 114 on the frame 106a cannot be electrically connected with each other through the underlying conductive leads 162 and 164 and the metal heat dissipation bulk 140a. Therefore, the electrode pads 112 and 114 are electrically separated from one another at the two sides of the trench 166. The conductive leads 162 and 164 can electrically connect the electrode pads 112 and 114 to the metal layer 136a of the metal heat dissipation bulk 140a on the portions 170 and 172 at the two sides of the trench 166 respectively.

In one exemplary embodiment, as shown in FIG. 3A and FIG. 3B, the trench 166 may be further filled with the insulation layer 168 to increase the electrical insulation reliability of the electrode pads 112 and 114 at the two sides of the trench 166.

In the present embodiment, with the trench 166, the electrode pad 112 can be electrically connected to an electrode of the outer power supply through the conductive lead 162 and the portion 170 of the metal heat dissipation bulk 140a at one side of the trench 166. The electrode pad 114 can be electrically connected to the other electrode of the outer power supply through the conductive lead 164 and the portion 172 of the metal heat dissipation bulk 140a at another side of the trench 166. Therefore, the light-emitting diode chip 120 can be electrically connected to the outer power supply by a surface mount method to directly adhere the metal heat dissipation bulk 140a to an electrode board or a circuit board. Now, the metal heat dissipation bulk 140a can be used as an electrode in a surface mount technology.

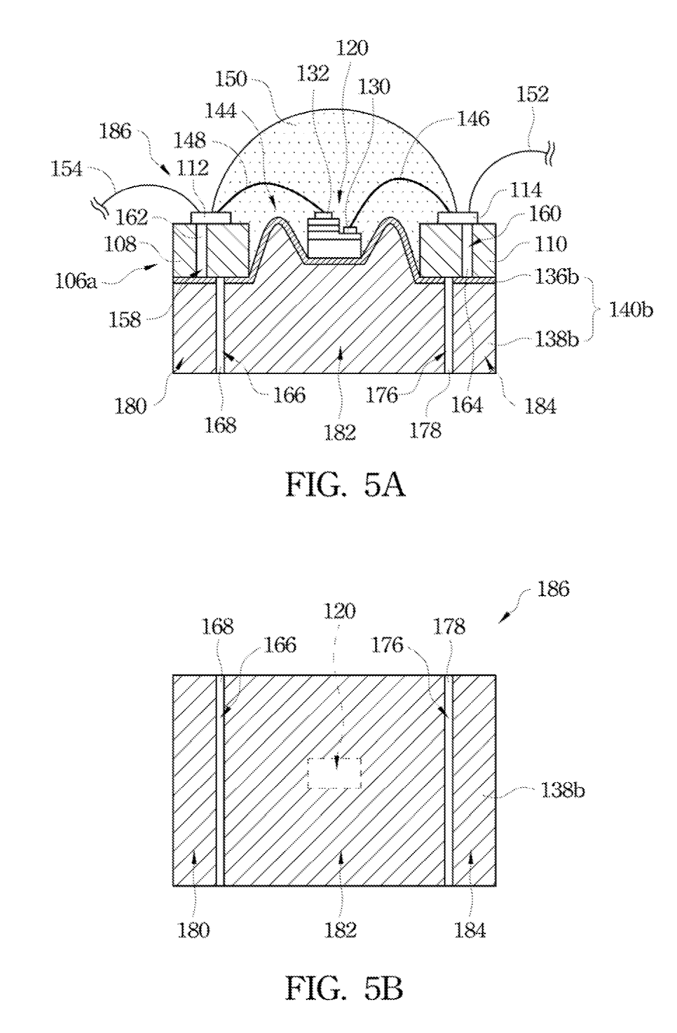

A metal heat dissipation bulk of a light-emitting diode device of the present invention can include two trenches to provide the light-emitting diode device with a heat-electricity separated operation property. Refer to FIG. 5A and FIG. 5B. FIG. 5A and FIG. 5B respectively illustrate a cross-sectional view and a back view of a light-emitting diode device in accordance with further another embodiment of the present invention. In the present embodiment, a structure of a light-emitting diode device 186 is substantially the same as that of the light-emitting diode device 174 of the aforementioned embodiment. A main difference between the light-emitting diode devices 174 and 186 is that compared with the metal heat dissipation bulk 140a, a metal heat dissipation bulk 140b composed of a metal layer 136b and a metal heat dissipation layer 138b further includes a trench 176 in addition to the trench 166. That is in the present embodiment, while the trench 166 is formed, the other trench 176 is formed in the metal heat dissipation bulk 140b.

In one exemplary embodiment, when the trenches 166 and 176 are formed, the frame 106a needs to provide supports to two sides of the whole structure to ensure that the whole structure can be supported well, so that the locations of the trenches 166 and 176 are preferably located within the scope of the frame 106a. As shown in FIG. 5A, one opening at one end of the trench 166 exposes a partial surface of the portion 108 of the frame 106a, and one opening at one end of the trench 176 exposes a partial surface of the portion 110. In another exemplary embodiment, the metal heat dissipation bulk 140b including the trenches 166 and 176 may be formed similarly by an electroless plating method.

As shown in FIG. 5A and FIG. 5B, in the light-emitting diode device 186, the trenches 166 and 176 are respectively formed at two sides of the light-emitting diode chip 120, and the trenches 166 and 176 are respectively located between the conductive lead 162 and the light-emitting diode chip 120 and between the conductive lead 164 and the light-emitting diode chip 120. In addition, the trenches 166 and 176 both pass through the metal heat dissipation bulk 140b to divide the metal heat dissipation bulk 140b into three portions 180, 182 and 184. Therefore, with the trenches 166 and the 176, the electrode pads 112 and 114 on the frame 106a cannot be electrically connected with one another through the underlying conductive leads 162 and 164 and the metal heat dissipation bulk 140b. Therefore, the electrode pads 112 and 114 are electrically separated from one another at the two sides of the trench 166 or 176. The conductive leads 162 and 164 can electrically connect the electrode pads 112 and 114 to the metal layer 136b of the metal heat dissipation bulk 140b on the portion 180 at an outer side of the trench 166 and the portion 184 at an outer side of the trench 176 respectively.

In one exemplary embodiment, as shown in FIG. 5A and FIG. 5B, the trenches 166 and 176 may be further respectively filled with insulation layers 168 and 178 to increase the electrical insulation reliability of the electrode pads 112 and 114 at the two sides of the trench 166 or 176.

In the present embodiment, with the trenches 166 and 176, the electrode pad 112 can be electrically connected to an electrode of the outer power supply through the conductive lead 162 and the portion 180 of the metal heat dissipation bulk 140b at the outer side of the trench 166. The electrode pad 114 can be electrically connected to the other electrode of the outer power supply through the conductive lead 164 and the portion 184 of the metal heat dissipation bulk 140b at the outer side of the trench 176.

Furthermore, the portion of the metal heat dissipation bulk 140b underlying the light-emitting diode chip 120 is separated from the conductive leads 162 and 164 respectively by the trenches 166 and 176, so that heat generated from the operating of the light-emitting diode chip 120 is mainly conducted by the portion 182 of the metal heat dissipation bulk 140b between the trenches 166 and 176. Therefore, the portions of the metal heat dissipation bulk 140b for conducting electricity and heat of the light-emitting diode chip 120 are separated. That is the light-emitting diode device 186 has a heat-electricity separated operation property. Similarly, the light-emitting diode chip 120 can be electrically connected to the outer power supply by a surface mount method to directly adhere the metal heat dissipation bulk 140b to an electrode board or a circuit board. Now, the metal heat dissipation bulk 140b can be used as an electrode in a surface mount technology.

According to the aforementioned embodiments, one advantage of the present invention is that a light-emitting diode device and a method for manufacturing the same of the present invention can use a hot melt adhesive material to simultaneously fix a light-emitting diode chip and a frame, so that the process is simple and is easy to be implemented.

According to the aforementioned embodiments, another advantage of the present invention is that in a light-emitting diode device and a method for manufacturing the same of the present invention, a hot melt adhesive is formed on a side surface of a light-emitting diode chip, so that it can ensure that the side surface of the light-emitting diode chip is not covered by a metal heat dissipation bulk, thereby effectively preventing lateral light of the light-emitting diode chip from being reflected by the metal heat dissipation bulk covered on the side surface of the light-emitting diode chip. Therefore, the lateral light extraction efficiency of the light-emitting diode device is increased, and the light-emitting efficiency of the light-emitting diode device is enhanced.

According to the aforementioned embodiments, still another advantage of the present invention is that in a light-emitting diode device and a method for manufacturing the same of the present invention, a hot melt adhesive is formed on a side surface of a frame, so that when a metal heat dissipation bulk is formed subsequently, it can ensure that the side surface of the frame is not covered by the metal heat dissipation bulk. Therefore, it can effectively prevent a short circuit between electrode pads on the frame and the metal heat dissipation bulk from occurring, thereby greatly enhancing the process yield and the product reliability.

According to the aforementioned embodiments, further another advantage of the present invention is that in a light-emitting diode device and a method for manufacturing the same of the present invention, a bottom of a light-emitting diode chip is directly connected with a metal heat dissipation bulk, so that the light-emitting diode device has superior heat dissipation efficiency.

According, to the aforementioned embodiments, yet another advantage of the present invention is that in a light-emitting diode device and a method for manufacturing the same of the present invention, a cup structure for packaging is unnecessary.

According to the aforementioned embodiments, still further another advantage of the present invention is that in the present invention, metal can be used to form a body of a frame, so that the light-emitting diode device has better heat dissipation efficiency.

According to the aforementioned embodiments, yet further another advantage of the present invention is that in the present invention, when a cavity for receiving a light-emitting diode chip is formed in a metal substrate of a frame, conductive leads of the light-emitting diode device can be simultaneously formed in the metal substrate by a simple mechanical processing method. Therefore, the manufacturing of the conductive leads of the light-emitting diode device is easy.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A light-emitting diode device, including:
a metal heat dissipation bulk including a curve protrusion ring;
a frame disposed on the metal heat dissipation bulk outside the curve protrusion ring, wherein the frame includes at least two electrode pads respectively disposed at two sides of the curve protrusion ring;
a light-emitting diode chip disposed on the metal heat dissipation bulk in an inner side of the curve protrusion ring, wherein the light-emitting diode chip has a first electrode and a second electrode of different conductivity types, and the first electrode and the second electrode are electrically connected to the electrode pads respectively; and
a package encapsulant encapsulating the light-emitting diode chip, the curve protrusion ring, and a portion of each of the electrode pads.

2. The light-emitting diode device according to claim 1, further including two wires respectively connecting the electrode pads to an outer power supply.

3. The light-emitting diode device according to claim 1, wherein the metal heat dissipation bulk includes a metal heat dissipation layer and a metal layer covering the metal heat dissipation layer.

4. The light-emitting diode device according to claim 3, wherein
the metal heat dissipation bulk is further set with a first trench passing through the metal heat dissipation bulk to electrically separate the electrode pads at two sides of the first trench; and
the frame is further set with two through holes passing through the frame, and the frame includes two conductive leads respectively disposed in the through holes to electrically connect the electrode pads to the metal heat dissipation bulk at the sides of the first trench respectively.

5. The light-emitting diode device according to claim 4, wherein the metal heat dissipation bulk is further set with a second trench, and the first trench and the second trench are located at two sides of the light-emitting diode chip.

6. The light-emitting diode device according to claim 5, wherein the metal heat dissipation bulk further includes two insulation layers respectively filling the first trench and the second trench.

7. The light-emitting diode device according to claim 4, wherein the metal heat dissipation bulk is a surface mounting electrode of the light-emitting diode chip, and the metal heat dissipation bulk is suitable to be directly adhered to an electrode board or a circuit board.

8. The light-emitting diode device according to claim 3, wherein a material of the metal layer is a metal material of high reflectivity, and the metal material of high reflectivity includes Ag, Pt, Al, Au, Ni or Ti.

9. The light-emitting diode device according to claim 3, wherein a material of the metal heat dissipation layer is Cu.

10. The light-emitting diode device according to claim 1, wherein the frame includes at least two insulation portions, and the electrode pads are respectively formed on the insulation portions.

11. The light-emitting diode device according to claim 1, wherein the frame includes a metal substrate and an insulation layer wrapping the metal substrate.

12. The light-emitting diode device according to claim 11, wherein
a material of the metal substrate includes Al or Cu; and
a material of the insulation layer includes aluminum oxide, silicon nitride or silicon dioxide.

13. A method for manufacturing a light-emitting diode device, including:
providing a temporary substrate, wherein a hot melt adhesive layer is formed on the temporary substrate;
embedding a frame into the hot melt adhesive layer, wherein the frame includes at least two portions, and each of the portions is set with an electrode pad;
embedding a light-emitting diode chip into the hot melt adhesive layer between the portions, wherein the light-emitting diode chip includes a first electrode and a second electrode of different conductivity types, and the hot melt adhesive layer has a curve cavity ring between the light-emitting diode chip and the frame;
forming a metal heat dissipation bulk to cover the frame, the light-emitting diode chip and the hot melt adhesive layer and to fill the curve cavity ring, so as to make the metal heat dissipation bulk include a curve protrusion ring;
removing the temporary substrate and the hot melt adhesive layer to expose the light-emitting diode chip, the first electrode, the second electrode, the frame, the electrode pads and the curve protrusion ring;
electrically connecting the first electrode and the second electrode to the electrode pads respectively; and
forming a package encapsulant to encapsulate the light-emitting diode chip, the curve protrusion ring and a portion of each of the electrode pads.

14. The method for manufacturing a light-emitting diode device according to claim 13, wherein a material of the hot melt adhesive layer includes ethylene-vinyl acetate, polyolefin polymer, polyamide resin or wax.

15. The method for manufacturing a light-emitting diode device according to claim 13, wherein the step of forming the metal heat dissipation bulk includes:
forming a metal layer to cover the frame, the light-emitting diode chip and the hot melt adhesive layer; and
forming a metal heat dissipation layer to cover the metal layer and to fill up the curve cavity ring.

16. The method for manufacturing a light-emitting diode device according to claim 15, further including forming the frame before the step of embedding the frame, wherein the step of forming the frame includes:
providing a flat metal plate;
forming a through cavity in the flat metal plate to form a metal substrate; and
forming an insulation layer to wrap the metal substrate.

17. The method for manufacturing a light-emitting diode device according to claim 15, further including forming the frame before the step of embedding the frame,
wherein the step of forming the frame includes:
forming two through holes to respectively pass through the portions,
wherein the through holes respectively expose portions of the electrode pads; and
forming two conductive leads to respectively fill the through holes; and
wherein the step of forming the metal heat dissipation bulk includes:
forming a first trench to pass through the metal heat dissipation bulk to electrically separate the electrode pads at two sides of the first trench, wherein the conductive leads electrically connect the electrode pads to the metal heat dissipation bulk at the sides of the first trench respectively.

18. The method for manufacturing a light-emitting diode device according to claim 17, wherein the step of forming the metal heat dissipation bulk further includes forming a second trench to pass through the metal heat dissipation bulk, and the first trench and the second trench are located at two sides of the light-emitting diode chip.

19. The method for manufacturing a light-emitting diode device according to claim 18, wherein the step of forming the metal heat dissipation bulk further includes forming two insulation layers to respectively fill the first trench and the second trench.

20. The method for manufacturing a light-emitting diode device according to claim 18, wherein the first trench and the second trench are simultaneously formed in the metal heat dissipation bulk as the metal layer and the metal heat dissipation layer are grown.

21. The method for manufacturing a light-emitting diode device according to claim 13, wherein the step of removing the temporary substrate and the hot melt adhesive layer includes:
performing a heating and melting treatment on the hot melt adhesive layer;
separating the temporary substrate and the hot melt adhesive layer; and
using an organic dissolvent to remove the hot melt adhesive layer.

22. The method for manufacturing a light-emitting diode device according to claim 13, further including cutting a redundant portion of the metal heat dissipation bulk after the step of removing the temporary substrate and the hot melt adhesive layer.

23. The method for manufacturing a light-emitting diode device according to claim 13, further including using two wires to respectively connect the electrode pads to an outer power supply before or after the step of forming the package encapsulant.
